(19) United States
(12) Patent Application Publication
(10) Pub. No.: US 2026/0022293 A1
(43) Pub. Date: Jan. 22, 2026

(54) ROOM TEMPERATURE POLARITON CONDENSATION

(71) Applicants: THE TRUSTEES OF INDIANA UNIVERSITY, Bloomington, IN (US); THE RESEARCH FOUNDATION OF THE CITY UNIVERSITY OF NEW YORK, New York, NY (US); UNIVERSITY OF COPENHAGEN, Copenhagen (DK)

(72) Inventors: Amar Hugh FLOOD, Bloomington, IN (US); Ravindra Kumar YADAV, Jersey City, NJ (US); Sitakanta SATAPATHY, Hamden, CT (US); Prathmesh DESHMUKH, Redmond, WA (US); Vinod MENON, New York, NY (US); Bo LAURSEN, Copenhagen (DK)

(21) Appl. No.: 18/998,431

(22) PCT Filed: Aug. 7, 2023
(86) PCT No.: PCT/US2023/029619

§ 371 Date: Jan. 24, 2025

Related U.S. Application Data
(60) Provisional application No. 63/370,565, filed on Aug. 5, 2022.

(51) Int. Cl. C09K 11/06; C09B 11/24; C09B 67/20; H01S 5/125

(52) U.S. Cl. CPC C09K 11/06; C09B 11/24; C09B 67/0065; H01S 5/125; C09K 2211/1007; C09K 2211/1011; C09K 2211/1018

(57) ABSTRACT

Disclosed herein is a microcavity and patterns thereof comprising a photoluminescent material positioned between two reflectors, wherein the photoluminescent material comprises a cationic molecular dye, a macrocyclic anion receptor host, and an anion embedded within the macrocyclic anion receptor host and methods of making and using the same.

### CROSS-REFERENCE TO RELATED APPLICATIONS

This application claims benefit of priority to, and incorporates herein by reference in its entirety U.S. Provisional Application Ser. No. 63/370,565, filed Aug. 5, 2022.

### STATEMENT REGARDING FEDERALLY SPONSORED RESEARCH

This invention was made with government support under 2118423 and 1936351 awarded by National Science Foundation. The Government has certain rights in the invention.

### BACKGROUND OF THE INVENTION

Despite the realization of room temperature polariton condensates using a few molecular solids, the basic design principle for realizing condensation in organic microcavities remain unclear. There is some confusion in the selection of molecular emitters to achieve condensation which arises due to the co-existing positive disorder effects, such as disorder potential, and negative effects, including wrong transition dipole moment orientation, misaligned molecules induced Förster transfer, and energy/angular broadened polariton states.³ Although, a substantial amount of research is currently focused on reducing the threshold for polariton lasing, a targeted chemistry behind the optimal design of an emitter is yet to be unraveled.

### BRIEF SUMMARY OF THE INVENTION

Disclosed herein are devices and methods for forming a polariton at room temperature. One aspect provides for a microcavity comprising a photoluminescent material positioned between two reflectors. The photoluminescent material comprises a cationic molecular dye, a macrocyclic anion receptor host, and an anion embedded within the macrocyclic anion receptor host. Some exemplary macrocyclic anion receptor hosts include polycyanostilbenes, such as

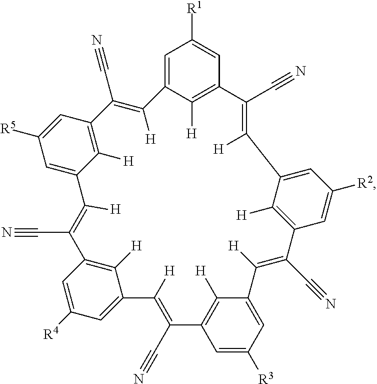

where substituents R¹, R², R³, R⁴, and R⁵ are defined therein. The positioning of the reflectors may be chosen to allow a standing wave through the photoluminescent material. The cavity detuning of the microcavity may be chosen to keep the energy difference between the uncoupled exciton and ko of an LP mode to be in resonance with a vibron of the photoluminescent material. The photoluminescent material may be a thin film. The photoluminescent material may also be pattered into a lattice pattern, a honeycomb pattern, a stripped pattern, a crosshatch pattern, a hole pattern, or trench pattern. Additionally, or alternatively, the photoluminescent material may be patterned with any number of arbitrary features.

Another aspect of the technology provides for methods of using the microcavities described herein may include methods for forming a polariton by irradiating any of the microcavities described herein.

Another aspect of the technology provides for methods for emitting photons from any of the irradiated microcavities described herein.

Yet another aspect of the technology provides for methods for preparing the microcavities described herein. The method may comprise forming any of the photoluminescent materials described herein onto a reflector substrate and optionally forming a reflector on the formed photoluminescent material opposite the reflector substrate. The photoluminescent material may be optionally patterned.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention.

FIG. 1: Materials and thin film optics. Chemical structure of the reactant precursors and R3B-SMILES.

FIGS. 2A, 2B, and 2C: FIG. 2A) Power dependent photoluminescence (PL) intensity comparison for bare R3B and R3B-SMILES thin films (inset shows the bright PL from the respective films) and measured polar plots showing the normalized intensity distribution regions for the (FIG. 2B) R3B and (FIG. 2C) R3B-SMILES thin films.

FIG. 3: Organic microcavity and relevant energy levels. Schematic of the organic microcavity, consisting of a 35-nm spin-coated film of R3B-SMILES, sandwiched between a bottom SiO₂/TiO₂ distributed Bragg reflector and a top Ag mirror.

FIGS. 4A and 4B: FIG. 4A) Experimental white light reflectivity plots obtained from the cavity sample. The lines denote coupled oscillator mode fits. Dashed lines indicate the bare cavity dispersion and S₁₀ main exciton of R3B-SMILES. The solid lines correspond to the lower (LP, solid line) and upper (UP, solid line) polariton branches, respectively. FIG. 4B) Left panel shows the normalized absorbance and PL spectra of R3B-SMILES thin film, middle panel shows the angle-dependent white light reflectivity plot showing the dispersion fit results only for the respective exciton, cavity and polariton modes and right panel shows the Raman spectra of a thin film of R3B-SMILES. The exciton-cavity detuning is chosen to align the ground polariton state at one vibronic energy quantum of 90 meV below the exciton reservoir. Energy relaxation from the reservoir occurs with the emission of a single vibron (depicted by grey solid vertical arrow and a dark red Newtonian spring).

FIGS. 5A and 5B: Collapse of polariton photoluminescence. Angle resolved PL intensity dispersion plots of the LP branch (FIG. 5A) below threshold (<Pₜₕ) and (FIG. 5B) at and above the threshold (≥Pₜₕ). Inset shows the real-space PL intensity plots of the LP branch corresponding to the respective excitation powers depicting 16-fold enhancement in emission intensity and highlighting the collapse of the emission to a central spot near the pump centroid at Pₜₕ.

FIGS. 6A and 6B: Characteristic hallmarks of optical nonlinearity. FIG. 6A) Integrated PL intensity along with linewidth. Note the threshold ˜10 mJ cm⁻². FIG. 6B) The corresponding emission spectra. Note the blueshift and superlinear increase beyond Pₜₕ.

FIG. 7: Experimentally observed blueshifts as a function of different excitation powers for the cavity sample. The fit results are integrated around k=±2⁰.

FIG. 8: Polar plot depicting the emission intensity with respect to the angle of a polarizer in front of the detector at 0.75 (black) and 1.25 Pₜₕ (magenta) excitation power. The structure on the polarization lobes in the condensation regime originates from the before mentioned highly nonlinear amplified excitation pulse fluctuations.

FIG. 9: Spatial coherence. Interferograms recorded using a Michelson interferometer configuration for increasing pump fluence. The fringes observed at each point r are indicative of the spatial coherence between it and its centrosymmetric counterpart −r. As threshold is reached, the emission spot collapses and fringes emerge from the pump center. Beyond approximately 1.2 Pₜₕ, fringes are observed over the entire condensate area indicative of macroscopic phase coherence throughout the condensate.

FIG. 10: (a) Schematic of the planar microcavity. (b) White light angle-dependent reflectivity of the plainer cavity region fitted with a coupled oscillator model. (c) Structure of a patterned organic exciton-polariton cavity. (d) SEM image of a single pillar, honeycomb unit cell, and lattice patterned on the planer cavity using FIB etching technique.

FIG. 11: Fourier imaging microscopy (FIM) imaging was used for parts (a, b, e, f). (a) Angle-dependent gradient photoluminescence (PL) intensity on the plainer cavity region. (b) Angle-dependent gradient PL intensity on a single pillar with a diameter of 2.75 μm. (c) Calculated angle-dependent emission on a single pillar with a diameter of 2.75 μm. (d) Measured Brillouin zone (BZ) of the honeycomb lattice at the Dirac energy. (e) Experimental measured band structure along line 1 in the first Brillouin zone (BZ) (indicated by the black dotted line in (d)). (f) Experimental measured band structure along line 2 in the first Brillouin zone (BZ) (indicated by the black dotted line in (d)).

FIG. 12: (a) Real space image of lattice photoluminescence (PL) at a pumping power of 0.5 times the threshold power (Pₜₕ). (b) Real space image of lattice PL at a pumping power of 1.25 times the threshold power (Pₜₕ).

### DETAILED DESCRIPTION OF THE INVENTION

Disclosed herein is materials and systems for room temperature polariton condensation using a molecular dye embedded into a macrocyclic anion receptor host. The chemical structure of the host-guest complex is highly fluorescent due to the intermixing of the molecular dye with the host. The formation of the host-guest complex results in an enhancement in the photoluminescence (PL) quantum yield in comparison to the bare molecular dye. The complexes also provide for improved photostability in comparison to the bare molecular dye.

The disclosed technology allows for the manufacture of polariton lasers and polariton condensates in an easy and modular way using Small-molecule ionic isolation lattices (SMILES) materials such that the lasers and condensates can be made with almost any color. The SMILES material also demonstrates higher damage threshold to laser power and superior performance at high pump power (e.g., low exciton-exciton annihilation). These materials are also resilient to processing conditions for making microcavities.

Exciton-polaritons, light-matter quasiparticles that emerge when the electronic excitations hybridize with the electromagnetic radiation, have become a platform for both fundamental investigations and technological developments. The hybrid nature of these quasiparticles lends them the advantages of both light and matter. In a cavity geometry where the electromagnetic field is confined, the exciton-polaritons acquire a small effective mass which becomes a major advantage in the context of realizing Bose Einstein condensation (BEC) at elevated temperatures.

While early experiments on polariton condensation focused on inorganic semiconductors hosting Wannier excitons, for over a decade now there has been much interest in realizing condensation using large binding energy Frenkel excitons hosted in organic molecular solids. These allow realization of strong coupling at room temperature. Most polariton condensates reported to date are not true BECs since they are not at thermal equilibrium. However, they do exhibit some of the novel features like superfluidity and, in analogy to cold atom lattices, can be implemented as Hamiltonian emulators.⁷

There have been different material platforms that show polariton condensation at room temperature such as wide band gap semiconductors, 2D materials, perovskites and organic molecular solids. Of these, organic molecular system has especially garnered much attention owing to the promise of on demand tunability, fabrication on flexible substrates, and control of photophysical properties via well-established chemical synthesis techniques. Nevertheless, the demonstrations till date of organic polariton condensates have been carried out using few specific molecular systems ranging from single crystals to ladder type polymeric systems and fluorescent proteins. With the large body of organic fluorescent dyes available today, it would be ideal if one could choose any of these dyes to realize condensation to really unleash the power of organic fluorophores. This has not been conceivable till recently owing to the exciton-exciton annihilation under high exciton densities, difficulty to realize thin films in solid host matrices without compromising on the photo luminescence quantum yield, and the inherent orientational and structural disorder.

The SMILES materials described herein address the challenges of preparing polariton condensates are room temperature with organic materials. Aggregation-induced quenching (ACQ) and bimolecular/exciton-exciton annihilation is a long-standing problem that impacts the vast majority of the organic dyes and constitutes a bottleneck in materials creation for photonic applications. SMILES are formed by stoichiometric mixing of the cationic organic dyes with macrocycles, such as colorless anion-binding cyanostar (CS) macrocycles. The molecular design strategy allows major classes of commercial dyes, including styryls, xanthenes, trianguleniums, oxazines, triarylmethanes, cyanines, acridines, fluoronones, phenanthridines, polyaromatic hydrocarbons, imides, BODIPYs, coumarins, and squaraines, or a combination thereof to fully express their bright fluorescence in solid state. SMILES have result in the formation of the bright emitters (e.g., volume-normalized brightness >7,000 M⁻¹ cm⁻¹/nm³). Along with the strong resistance to exciton-exciton annihilation/bimolecular quenching at higher excitation densities, the material is also strongly tolerant to extended laser pulses. The disclosed SMILES system can be used for realizing exciton-polariton condensation in wide variety of dyes covering wide spectral range.

One aspect of the technology provides for microcavities having a photoluminescent material between two reflectors. A microcavity is a resonator that can trap light on a scale comparable with its wavelength. The reflectors allow for the entrapment of photons by reflecting photons that are being emitted by the photoluminescent material within the microcavity. Various properties can be exploited by the selection of the microcavity geometry.

The photoluminescent material of the disclosed invention is comprised of a cationic molecular dye, a macrocyclic anion receptor host, and an anion embedded within the macrocyclic anion receptor host. Photoluminescent materials are materials which are sensitive to light exposure. Photoluminescent materials absorb light at a certain wavelength and emit light at another wavelength.

An aspect of the disclosed invention includes the use of cationic molecular dyes. Molecular dyes are compounds which are used to impart color to a substate. Cationic molecular dye are dyes which can be dissociated into positively charged ions in aqueous solution. Neutral dyes can be converted from neutral dyes to cationic dyes under appropriate conditions. These dyes may comprise styryls, xanthenes, trianguleniums, oxazines, triarylmethanes, cyanines, acridines, fluoronones, phenanthridines, polyaromatic hydrocarbons, imides, BODIPYs, coumarins, and squaraines, or a combination thereof. An aspect of the disclosed invention describes a macrocyclic anion receptor host. An anion receptor host is a molecule designed to respond to a species that carries a negative charge. A macrocyclic anion receptor host embodies a molecule and ions containing a ring of twelve or more atoms that respond to a negatively charged species.

In an aspect, a photoluminescent material of Formula (I) is provided: (charged dye^{m+})ₓ(counterionⁿ⁻)_{y}·(counterion receptor)_{z} (I). The charged dye^{m+} is a cationic dye, the counterionⁿ⁻ is an anion and the counterion receptor is a macrocycle that functions as a binding ligand for the counterionⁿ⁻. The values of m, n, x, y, and z are integers greater than or equal to 1. Suitably, the stoichiometric ratio of the charged dye or the counterion to the macrocyclic counterion receptor host is between 2.0:1.0 and 1.0:4.0, 1.5:1.0 and 1.0:4.0, 1.0:1.0 and 1.0:4.0, 1.0:1.5 and 1.0:3.5, or 1.0:2.0 and 1.0:3.0. For example, the stoichiometric ratio of the charged dye or the counterion to the macrocyclic counterion receptor host may be about 2.0:1.0, 1.9:1.0, 1.8:1.0, 1.7:1.0, 1.6:1.0, 1.5:1.0, 1.4:1.0, 1.3:1.0, 1.2:1.0, 1.1:1.0, 1.0:1.1, 1.0:1.2, 1.0:1.3, 1.0:1.4, 1.0:1.5, 1.0:1.6, 1.0:1.7, 1.0:1.8, 1.0:1.9, 1.0:2.0, 1.0:2.1, 1.0:2.2, 1.0:2.3, 1.0:2.4, 1.0:2.5, 1.0:2.6, 1.0:2.7, 1.0:2.8, 1.0:2.9, 1.0:3.0, 1.0:3.1, 1.0:3.2, 1.0:3.3, 1.0:3.4, 1.0:3.5, 1.0:3.6, 1.0:3.7, 1.0:3.8, 1.0:3.9, or 1.0:4.0.

In an aspect, compounds of Formula (I) are prepared with naturally cationic dyes or neutral dyes initially converted to cationic dyes or anionic dyes converted to cationic dyes. Accordingly, the charged dye^{m+} of Formula (I) (that is, the cationic dye) can be prepared by one of the following methods. In one method, a neutral dye can be converted to the charged dye^{m+} with the addition of acid HX, where X is the counterionⁿ⁻ in compound of Formula (I). In some embodiments, the preparation of the charged dyeⁿ⁺ of Formula (I) by converting a neutral dye to the charged dye^{m+} includes adding an acid HX to the neutral dye, wherein the acid HX is selected from the group consisting of HPF₆, HBF₄ and HClO₄.

In an aspect, the macrocyclic anion receptor host may comprise: Formulas (II), (III), (IV) (V), (B.1), (B.2), or (B.3):

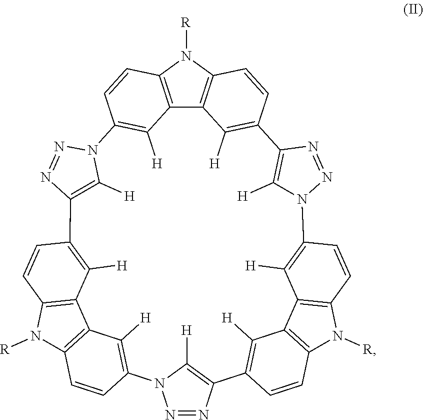

The R of Formula (II) are selected from a group consisting of alkyl (for example, C₁-C₁₈), alkyl-substituted phenyl derivatives, and substituted glycol derivatives, alkenyl, alkoxy, alkyl-NH-alkyl, aryl, cycloalkyl, heteroaryl, heterocycle, haloalkyl, hydrogen, iodo, —OR₆, —N(R⁷R⁸), —CO₂R⁹, —C(O)—N(R¹⁰R¹¹), wherein R⁶, R⁷, R⁸, R⁹, R¹⁰, and R¹¹ are each selected from the group consisting of alkenyl, alkyl, alkoxy, alkyl-NH-alkyl, aryl, arylalkyl, cycloalkyl, heteroaryl, heterocycle, haloalkyl, and hydrogen, among others, or a combination thereof.

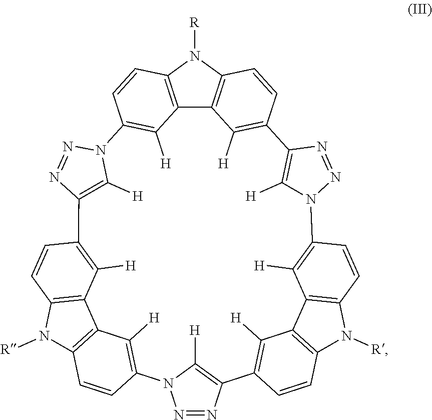

The R, R′ and R″ of Formula (III) are selected from a group consisting of alkyl (for example, C₁-C₁₈), alkyl-substituted phenyl derivatives, and substituted glycol derivatives, alkenyl, alkoxy, alkyl-NH-alkyl, aryl, cycloalkyl, heteroaryl, heterocycle, haloalkyl, hydrogen, iodo, —OR⁶, —N(R⁷R⁸), —CO₂R⁹, —C(O)—N(R¹⁰R¹¹), wherein R⁶, R⁷, R⁸, R⁹, R¹⁰, and R¹¹ are each selected from the group consisting of alkenyl, alkyl, alkoxy, alkyl-NH-alkyl, aryl, arylalkyl, cycloalkyl, heteroaryl, heterocycle, haloalkyl, and hydrogen, among others, or a combination thereof. The R, R′ and R″ of Formula (III) can be independently selected from each other or identical.

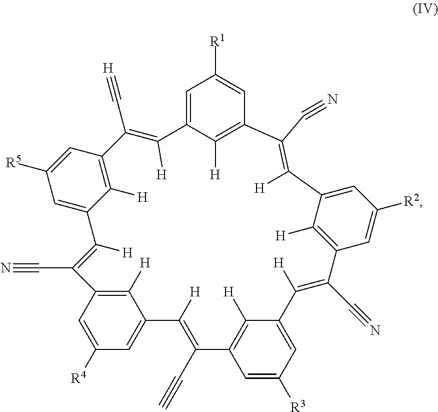

The R¹, R², R³, R⁴, and R′ of Formula (IV) are selected from a group consisting of alkyl (for example, C₁-C₁₈), alkyl-substituted phenyl derivatives, and substituted glycol derivatives, alkenyl, alkoxy, alkyl-NH-alkyl, aryl, cycloalkyl, heteroaryl, heterocycle, haloalkyl, hydrogen, iodo, —OR⁶, —N(R⁷R⁸), —CO₂R⁹, —C(O)—N(R¹⁰R¹¹), wherein R⁶, R⁷, R⁸, R⁹, R¹⁰, and R¹¹ are each selected from the group consisting of alkenyl, alkyl, alkoxy, alkyl-NH-alkyl, aryl, arylalkyl, cycloalkyl, heteroaryl, heterocycle, haloalkyl, and hydrogen, among others, or a combination thereof. The R¹, R², R³, R⁴, and R⁵ of Formula (IV) are identical.

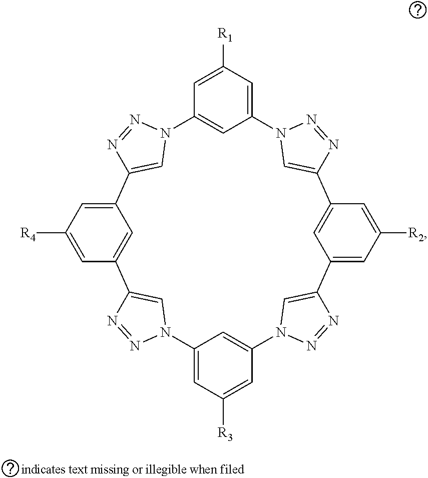

The R₁, R₂, R₃ and R₄ of Formula (V) are selected from a group consisting of alkyl (for example, C₁-C₁₈), alkyl-substituted phenyl derivatives, and substituted glycol derivatives, alkenyl, alkoxy, alkyl-NH-alkyl, aryl, cycloalkyl, heteroaryl, heterocycle, haloalkyl, hydrogen, iodo, —OR⁶, —N(R⁷R⁸), —CO₂R⁹, —C(O)—N(R¹⁰R¹¹), wherein R⁶, R⁷, R⁸, R⁹, R¹⁰, and R¹¹ are each selected from the group consisting of alkenyl, alkyl, alkoxy, alkyl-NH-alkyl, aryl, arylalkyl, cycloalkyl, heteroaryl, heterocycle, haloalkyl, and hydrogen, among others, or a combination thereof. The R₁, R₂, R₃ and R₄ of Formula (V) can be independently selected from each other or identical.

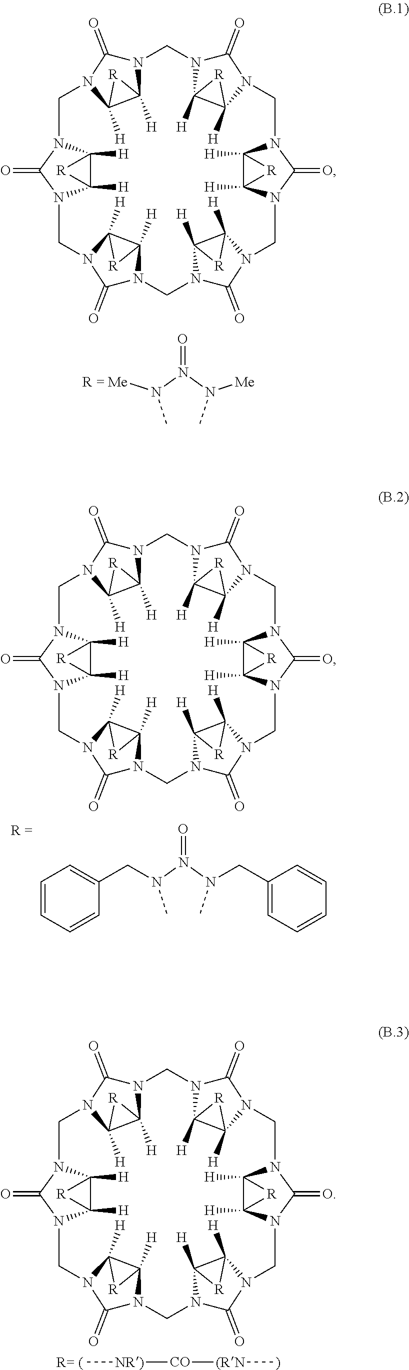

The R′ of Formula (B.3) are identical and are selected from a group consisting of alkyl (for example, C₁-C₁₈), alkyl-substituted phenyl derivatives, alkenyl, alkoxy, aryl, heteroaryl, heterocycle, and substituted forms of alkenyl, alkoxy, aryl, heteroaryl, and heterocycle groups.

With respect to the foregoing respects of the first aspect, the anion can be any anion, provided that the anion can form a chelation complex with the counterion receptor of Formula (I). Preferably, the anion is selected from the group consisting of BF₄⁻, ClO₄⁻, PF₆⁻, N(SO₂CF₃)₂⁻, N(SO₂Cl₂F₅)₂⁻, CH_{3S}O₃⁻, CF₃SO₃⁻, AsO₄³⁻, HASO₄²⁻, H₂AsO₄⁻, AsF₆⁻, AlCl₄⁻, PO₄³⁻, HPO₄²⁻, H₂PO₄⁻, SO₄²⁻, HSO₄⁻, Cl⁻, Br⁻, I⁻, cyanide, Br₄⁻, IO₄⁻, F⁻, HF₂⁻, TcO₄⁻, RPO₄²⁻, R₂PO₄⁻, RSO₃⁻, SCN⁻, N₃⁻, I₃⁻, CO₃⁻², HCO₃⁻, P₂O₇⁴⁻, HP₂O₇³⁻, H₂P₂O₇⁻, H₃P₂O₇⁻, RBF₃⁻, wherein R comprises a substituent. Certain anions which are excluded from Formula (I) include anions is selected from the group consisting of F5-TPB; tetrakis[3,5-bis(trifluoromethyl)phenyl]borate; tetrakis[3,5-bis(1,1, 1,3,3,3-hexafluoro-2-methoxy-2-propyl)phenyl]borate; Ar₄B⁻ (where Ar is aryl); TRISPHAT⁻; BINPHAT⁻.

The macrocyclic anion receptor host may comprise a polycyanostilbene. The cyanostilbene macrocycle may comprise of the following formula:

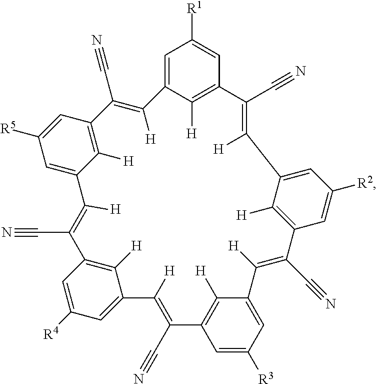

wherein R¹, R², R³, R⁴ and R⁵ are each independently selected from the group consisting of alkenyl, alkyl, alkoxy, alkyl-NH-alkyl, aryl, cycloalkyl, heteroaryl, heterocycle, haloalkyl, hydrogen, iodo, —OR⁶, —N(R⁷R⁸), —CO₂R⁹, —C(O)—N(R¹⁰R¹¹), and wherein R⁶, R⁷, R⁸, R⁹, R¹⁰, and R¹¹ are each independently selected from the group consisting of alkenyl, alkyl, alkoxy, alkyl-NH-alkyl, aryl, arylalkyl, cycloalkyl, heteroaryl, heterocycle, haloalkyl, and hydrogen. In some embodiments, the macrocyclic anion receptor host may comprise the following formula:

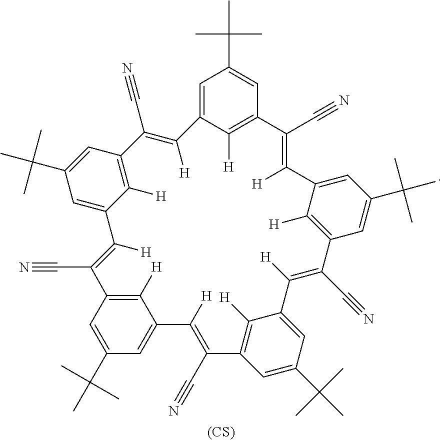

Exemplary photoluminescent materials are disclosed in US 2023/0167303, to Flood and Laursen, the contents of which is incorporated by reference in its entirety.

Without restricting the scope of these features, the stoichiometric ratio of cationic molecular dye or the anion to the macrocyclic anion receptor host is 1:2, In an aspect, the macrocyclic anion receptor host are arranged in a repeating constitutional units and the macrocyclic anion receptor host isolates the cationic molecular dye.

The complexation in a SMILES can have long range order that isolates the dyes from each other. Suitably, the cationic molecular dye and the macrocyclic anion receptor host may be arranged in a repeating constitutional unit. In some embodiments, the SMILES constitutional units are arranged in an alternating checkerboard pattern.

Geometry can affect the functionality of the microcavity where in a geometry where the electromagnetic field is confined, the exciton-polaritons acquire a small effective mass which becomes a major advantage in the context of realizing Bose Einstein condensation at elevated temperatures. For a bare dye, the dipoles are randomly aligned in three dimensions, while in the SMILES host, the dipoles are horizontally aligned (in-plane orientation), thus providing better coupling to the cavity photons in the Fabry-Perot geometry. Thus, in addition to the photostability and high quantum yield offered by the macrocycle host, it also provides ideal dipole orientation for enhanced light-matter interaction.

The reflectors may be comprised of a distributed Bragg reflector (DBR) or a mirror, e.g., a metal mirror or a photonic crystal mirror. The reflectors may be positioned to form a standing wave through the photoluminescent material.

In an aspect, the microcavity may comprise a cavity detuning that is chosen to keep the energy difference between the uncoupled exciton (reservoir) and ko of the LP mode to be in resonance the strongest vibron of the composition.

In some aspects, the photoluminescent material of the microcavity may be a thin film. A thin film is defined as a very thin layer of substance deposited in a layer. Without wishing to be bound by any particular theory, thin films generally have thicknesses between 10 nanometers and 2 micrometers. Thin films of photoluminescent material can be deposited by a thin film deposition method. Examples of thin film deposition techniques include drop casting or spin coating. Drop casting thin films can include dropping a solution of solvent and photoluminescent material onto a flat surface followed by evaporation of the solvent. Spin coating thin films can be used to spread a uniform thin film on a flat surface by centrifugal force.

In some aspects, the photoluminescent material can be patterned in such a way as to create various features. Some examples include without limitation a lattice pattern, a honeycomb pattern, a stripped pattern, a crosshatch pattern, a hole pattern, or trench pattern. In some instances, the photoluminescent material may be patterned with arbitrary features.

Another aspect of the technology provides a method for forming a polariton, where a polariton is a hybrid particle made up of a photon strongly coupled to an electric dipole. The method may comprise irradiating the microcavity as disclosed herein and further emitting a photon from an irradiated microcavity at an effective temperature. The microcavity may be irradiated with coherent and/or pulsed radiation. The methods can be practiced at a number of different temperatures, but in some embodiments the methods are practiced at room temperature.

Another aspect of the technology provides a method of preparing a microcavity. The method may comprise forming the photoluminescent material onto a reflector substrate, forming a reflector on the formed photoluminescent material opposite to the reflector substrate, patterning the formed photoluminescent materials, depositing a solution comprising the a cationic molecular dye, a macrocyclic anion receptor host, and an anion and evaporating solvent from the deposited solution, and spin coating the reflector substrate with the solution comprising a cationic molecular dye, a macrocyclic anion receptor host, and an anion and evaporating the solvent. Other methods for preparing the microcavity may also be used, such as imprint lithography.

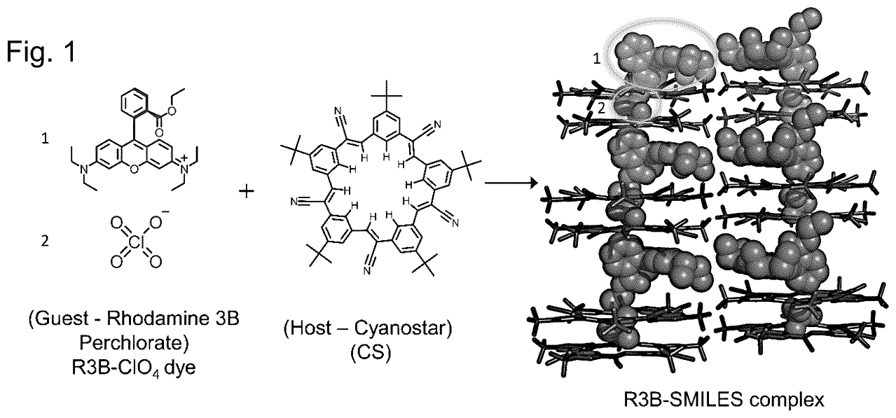

The Examples demonstrate the formation of room temperature polariton condensation using one of the most widely used molecular dye belonging to the class of Rhodamine embedded in the SMILES host. Specifically, we used Rhodamine 3B perchlorate, (R3B·ClO4)-SMILES integrated into a Fabry Perot microcavity structure to demonstrate condensation. The chemical structure of the host-guest complex system (R3B-SMILES) used in this study is shown in FIG. 1. The highly fluorescent molecular complex is formed via intermixing of R₃B.ClO₄ guest dye and CS (Cyanostar) host molecule in 1:2 stoichiometric ratio. The complexation in R3B-SMILES creates a molecular glue that makes the R3B.ClO₄ dyes stick together in a checkerboard like CS host and thus isolates them from one another in the alternating checkerboard pattern.

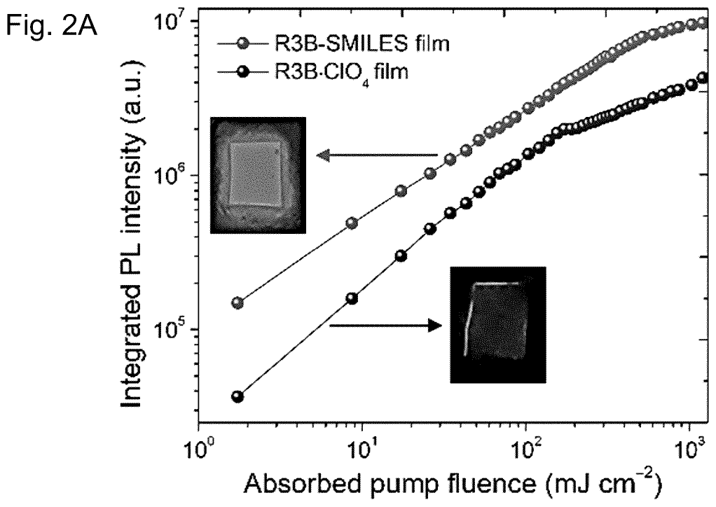

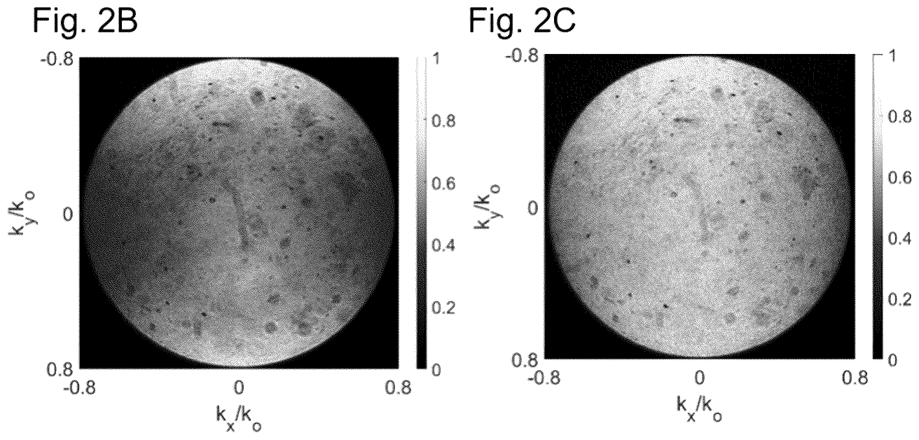

Consequently, this makes R3B-SMILES highly monomeric results in 10× enhancement in its photoluminescence (PL) quantum yield compared to the bare dye (R3B.ClO₄). The brightness and photostability comparison of thin films grown from bare R3B against R3B-SMILES is provided in FIG. 2A. The laser tolerance and resistance to exciton-exciton annihilation of the films are tested using a 10 kHz pulsed laser at 530 nm wavelength. The photobleaching threshold (573 mJ cm⁻²) of R3B-SMILES is found to be 5 times higher compared to the bare R3B. The bright surface emission of R3B-SMILES against almost negligible emission of bare R3B thin films (inset, FIG. 2A) prompted us to examine the orientation of transition-dipole-moments of both the molecules in a thin film state. We used Fourier imaging microscopy (FIM) to carry out the emission dipole imaging via PL measurements⁹. The line cut of the Fourier space image along kx is shown in FIG. 2B and 2C for both the bare dye and the R3B SMILES complex showing clear distinction in the orientation of the dipoles. For the bare dye, the dipoles are randomly aligned in three dimensions, while in the SMILES host, the dipoles are horizontally aligned (in-plane orientation), thus providing better coupling to the cavity photons in the Fabry-Perot geometry. Thus, in addition to the photostability and high quantum yield offered by the CS host, it also provides ideal dipole orientation for enhanced light-matter interaction.

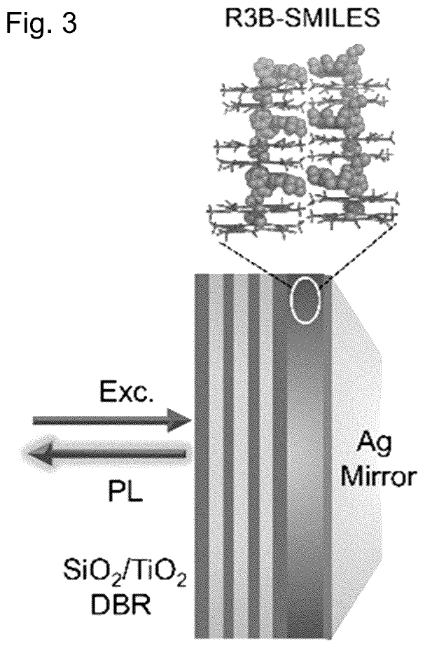

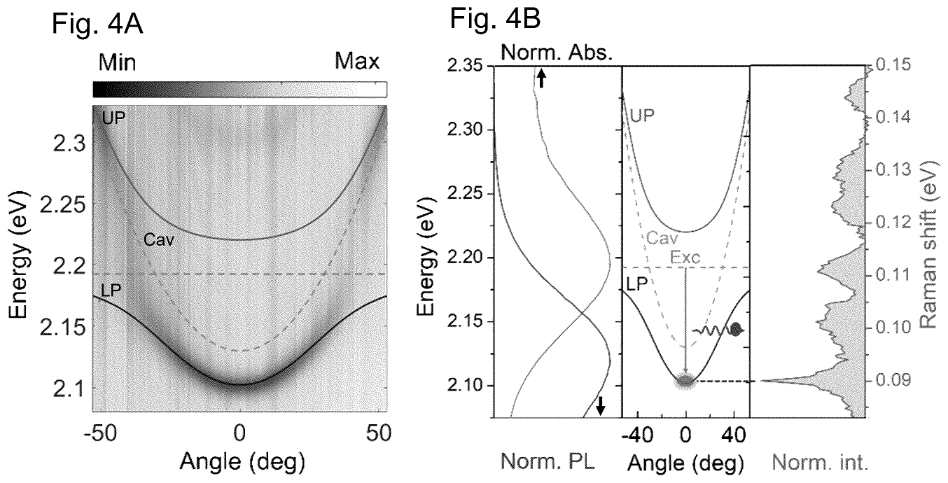

A schematic representation of the microcavity structure used for the present study is shown in FIG. 3. The microcavity is composed of a spin coated 30 nm thin film of R3B-SMILES sandwiched between silver top mirror and a bottom SiO2/TiO2 distributed Bragg reflector (DBR) on a quartz substrate resulting in a loaded Q-factor of ˜150. The experimental white light reflectivity obtained from the cavity sample using FIM is shown in FIG. 4A. Strong coupling of a Tamm cavity mode (2.11 eV) with the main exciton (S10 at 2.19 eV, as shown in the absorption spectrum plotted on the left panel of FIG. 4B) of R3B-SMILES resulted in two polariton branches with Rabi splitting, hΩ_{R}=138 meV. A similar microcavity comprising of the same concentration and thickness of the bare dye (R3B) film as active layer resulted in weak coupling despite the negligible difference in their excitation and emission energies compared to R3B-SMILES. This is attributed to the majority out-of-plane dipole orientation of the bare dye molecules compared to the predominantly in-plane dipole orientation in the R3B-SMILES complex.

An important consideration in the design of the microcavity was the detuning between the cavity mode and the excitonic transition at k_{μ}=0. We tuned the energetics of the cavity to facilitate the stimulated scattering to k₀, minima of the lower polariton mode. We designed the cavity detuning to keep the energy difference between the uncoupled exciton (reservoir) and k₀ of the LP mode to be in resonance the strongest vibron (˜90 meV) in R3B SMILES. This design ensures efficient stimulated scattering of the exciton reservoir via vibron-mediated relaxation to k₀ of the LP mode upon non-resonant excitation.

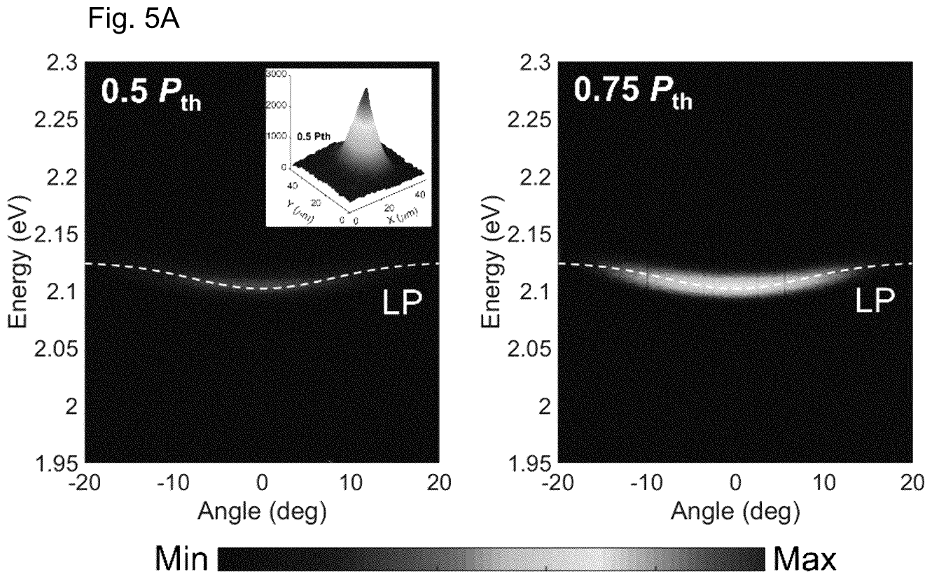

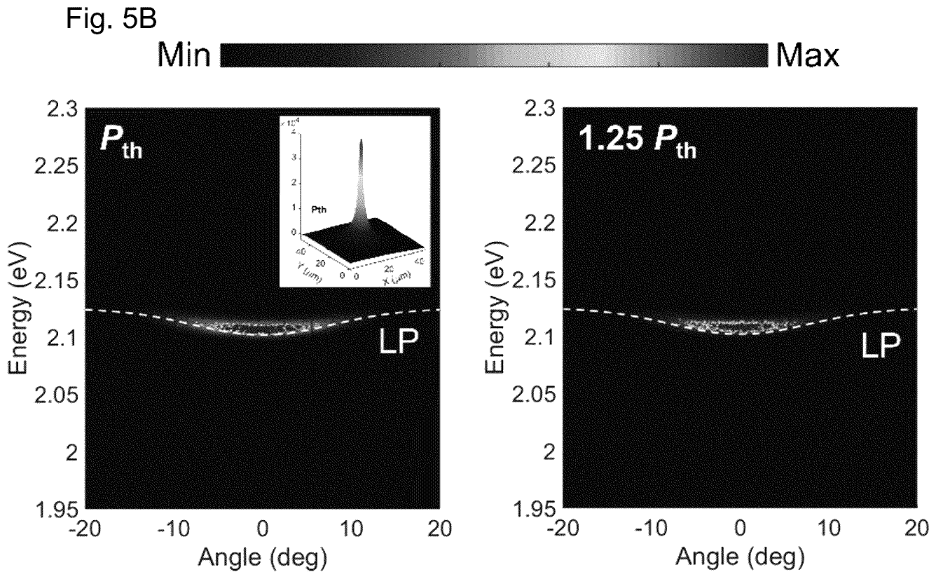

Following the demonstration of strong coupling in the R3B-SMILES cavity systems, we carried out pump fluence dependent luminescence studies. The cavity was pumped at 2.34 eV, corresponding to blue edge (reflectivity minimum) of the DBR using a 150 fs 10 KHz laser. The emission was imaged in the momentum space to study the modification of the dispersion under high polariton density. FIG. 5A and 5B show a comparison of the emission from the LP branch below and above threshold, clearly showing two important features: (i) the collapse in k-space above the threshold and (ii) the blue shift of the polariton emission. These are signatures of emergence of macroscopic coherence and polariton condensation (lasing) in the R3B-SMILES microcavity system. Real space data also shows the emission being dominated by the pump maxima indicating efficient stimulated scattering of polaritons. Note that the polariton condensation in R3B-SMLIES microcavity sample could be achieved under ambient conditions at a maximum pump repetition rate of 10 kHz, which is so far the highest repetition rate at which an organic polariton condensate has ever realized. This further demonstrates the tolerance of the SMILES platform against pump laser induced heat/O₂ induced bleaching and bimolecular annihilation as has been shown in the previous reports as well as in our pump dependent study of bare films (FIG. 2B).

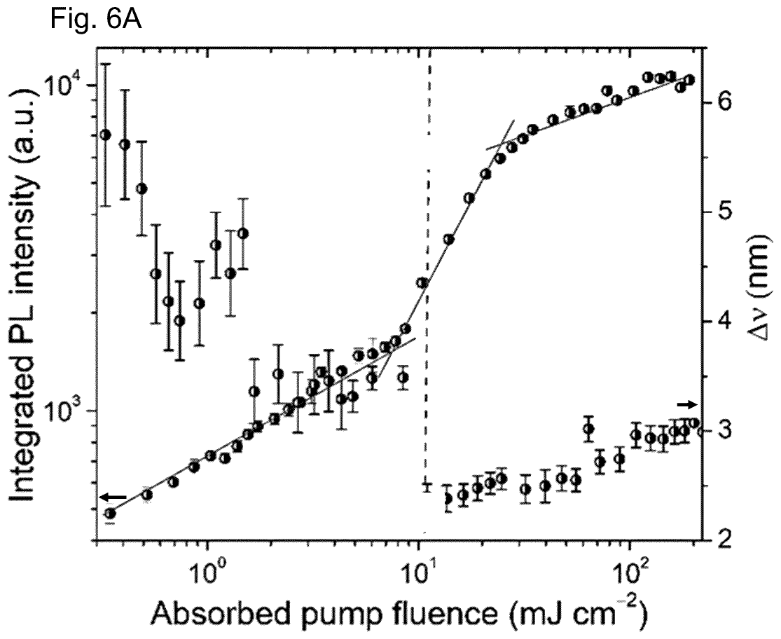

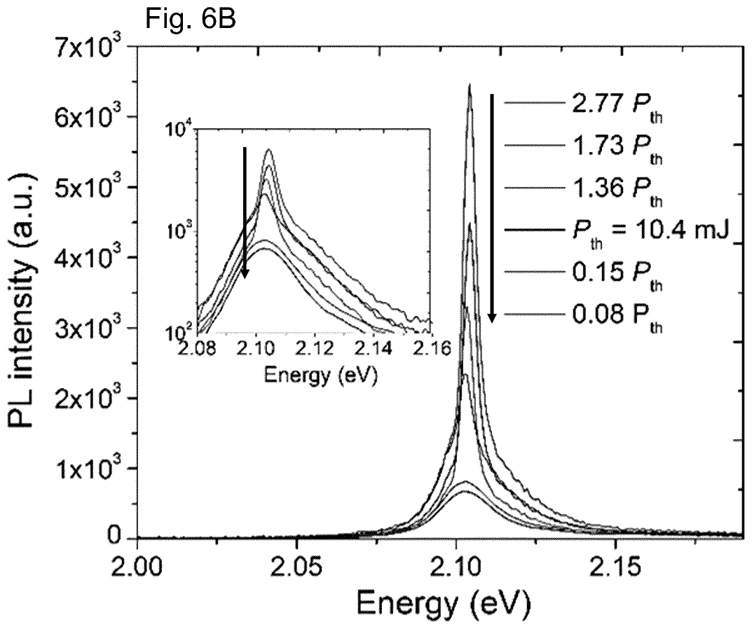

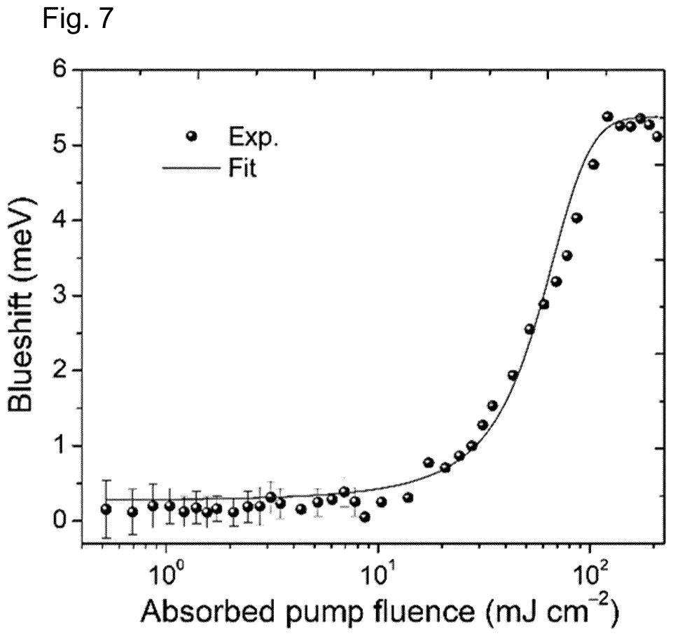

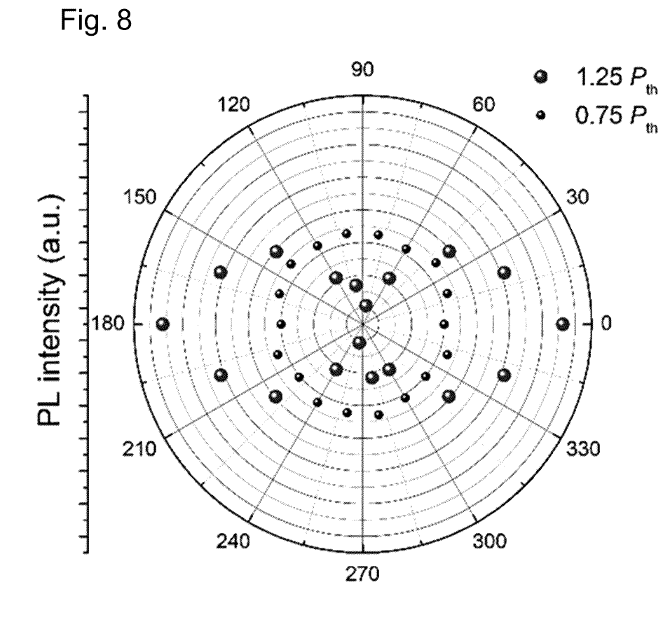

FIG. 6A shows the integrated PL intensity from the LP branch versus pump fluence. The gray-shaded line indicates the threshold at which a superlinear increase in PL intensity is observed. This is accompanied by the collapse in linewidth, indicative of the increase in temporal coherence. Beyond threshold, we find a power-dependent linewidth broadening. This behavior has been discussed extensively in previous reports and has been attributed to phase diffusion due to polariton self-interaction within the condensate and to condensation within different localized modes¹¹⁻¹⁴. The individual spectra, measured at normal incidence at k_{∥}=0, are shown in FIG. 6B. The emission spectrum shows distinct narrowing and almost an order of magnitude increase in peak intensity above threshold. Owing to the low Q-factor of the DBR-silver hybrid microcavity structure, the observed threshold is ˜10 mJ cm² which is high but comparable to the thresholds reported for some of the BODIPY dye-based cavity systems with all DBR mirrors with higher Q-factor. Note that we never observed lasing for cavities where ΔEₑₓ−ΔE_{LP}>90 meV (Δν_{Raman}), which further confirms the crucial role of vibron-mediated scattering to assist the condensation process.

We also observed an increase in energy blueshift after the condensation threshold, as shown in FIG. 6C. As discussed in previous reports,^{[+7]} the magnitude of blueshift in both the cavity samples is a combined effect resulting from the saturation-induced quenching of the Rabi splitting energy and the cavity mode energy renormalization because of the change in the effective refractive index (n_{eff}) of the cavity from exciting the weakly coupled or uncoupled molecules.

The polarization dependence of the microcavity PL at 0.5 Pₜₕ and 1.5 Pₜₕ are shown in FIG. 6D. The polarization of the condensate peak is pinned to the polarization of the excitation laser above the threshold with a degree of linear polarization of ˜73% is observed. This further confirms the spontaneous symmetry breaking in the condensate phase that manifest itself in the polarization of the emitted light.¹⁵

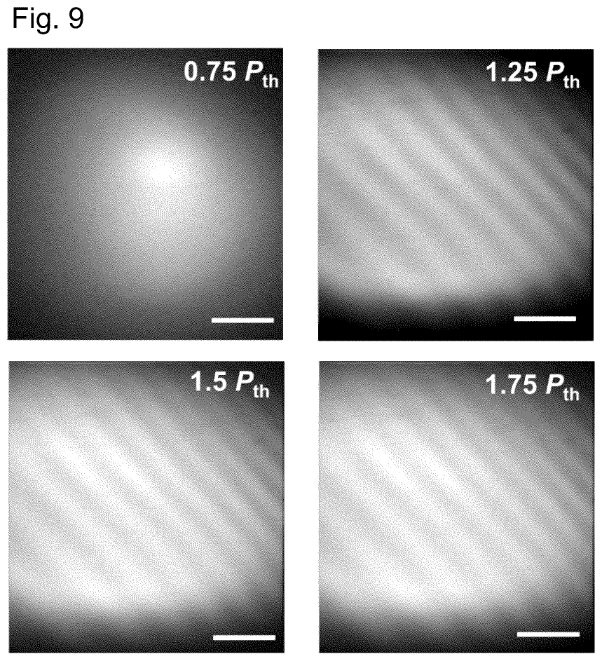

One of the defining features of condensate formation is the spontaneous appearance of off-diagonal long-range order which is physically manifested via the first-order spatial coherence g1 (r, r′)—a measure of the phase coherence between points at r and r′.^{13,16} FIG. 9 shows the interferogram produced by directly imaging the polariton condensate below and above the threshold power. We use a Michelson interferometer for generating optical interference between the emitted light by the cavity and its inverted image. Below threshold (0.5 Pₜₕ), the PL appears to be homogeneously distributed over the entire spot. Interference fringes at Pₜₕ begin to emerge from the center of the image, corresponding to a Gaussian pump profile. At this stage, the emission corresponds to a central condensed region with sub-threshold PL in the surrounding region. With increase in the pump fluence to P>1.2 Pₜₕ fringes are readily identified over the entire condensate area which clearly demonstrates the onset of long-range order. Upon fitting the interference fringes across the image with a convoluted Gaussian, we obtained a visibility contrast of 86% which indicates a high degree of spatial coherence across the condensate. From the standard deviation of the Gaussian fit we calculate a coherence length (λ_{c}=2√2 πσ) of 19.8 μm.

In summary, we have demonstrated a plug and play platform for realizing polariton condensates in organic molecular systems at room temperature. Using an archetypical organic dye, Rhodamine 3B perchlorate embedded in the CS host results in the R3B-SMILES complex which is integrated with a metal-DBR hybrid microcavity. The thin films of R3B-SMILES are extremely robust in terms of their photostability which is demonstrated by their strong tolerance to pump fluence and over five times improvement in photobleaching threshold compared to the bare dye film. In addition, the R3B-SMILES complex is also found to align the dipoles preferentially in the in-plane direction, thus enhancing the light-matter interaction strength. These unique aspects of the R3B-SMILES complex constitute the major driving force to successfully achieve room temperature condensation at a threshold excitation power of 10 mJ cm² in a DBR-metal cavity of moderate Q-factor (˜150). The observed polariton condensates show a large degree of spatial coherence with coherence length of ˜19.8 μm indicating large spatial uniformity and low disorder density in this system.

Since SMILES materials allows a wide variety of commercial organic dyes to fully express their bright photoluminescence in solid state, we envisage to extend our molecular design with multiple organic cationic dyes to approach a universal solution for emitter design for achieving on-demand low threshold polariton condensates under ambient conditions. The threshold can be further optimized and lowered in such cavities by identifying the correct high energy vibron-modes and tuning the polariton energetics as such to facilitate the stimulated scattering, while reducing the overlap of bare exciton absorption and emission bands to reduce self-absorption. Our results hold substantial promise for achieving a universal solution to the long-standing problem of an optimal emitter and microcavity design to achieve on-demand room temperature microcavity polariton condensates.

### Miscellaneous

Unless otherwise specified or indicated by context, the terms “a”, “an”, and “the” mean “one or more.” For example, “a molecule” should be interpreted to mean “one or more molecules.”

As used herein, “about”, “approximately,” “substantially,” and “significantly” will be understood by persons of ordinary skill in the art and will vary to some extent on the context in which they are used. If there are uses of the term which are not clear to persons of ordinary skill in the art given the context in which it is used, “about” and “approximately” will mean plus or minus ≤10% of the particular term and “substantially” and “significantly” will mean plus or minus >10% of the particular term.

As used herein, the terms “include” and “including” have the same meaning as the terms “comprise” and “comprising.” The terms “comprise” and “comprising” should be interpreted as being “open” transitional terms that permit the inclusion of additional components further to those components recited in the claims. The terms “consist” and “consisting of” should be interpreted as being “closed” transitional terms that do not permit the inclusion additional components other than the components recited in the claims. The term “consisting essentially of” should be interpreted to be partially closed and allowing the inclusion only of additional components that do not fundamentally alter the nature of the claimed subject matter.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

All references, including publications, patent applications, and patents, cited herein are hereby incorporated by reference to the same extent as if each reference were individually and specifically indicated to be incorporated by reference and were set forth in its entirety herein.

Preferred aspects of this invention are described herein, including the best mode known to the inventors for carrying out the invention. Variations of those preferred aspects may become apparent to those of ordinary skill in the art upon reading the foregoing description. The inventors expect a person having ordinary skill in the art to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

### EXAMPLES

Complexation of R3B-SMILES: The synthesis of Cyanostar (CS) host may be prepared according to literature procedure.⁵⁹ Around 20 mM of CS is added to 10 mM of R3B·ClO₄ (purchased from Exciton, Luxottica. Inc) in 1 mL of PMMA C2 solution. The solution is subjected to vigorous stirring for 48 hrs at room temperature to undergo complexation to form the R3B-SMILES complex. For the bare dye solution, 10 mM of R3B·ClO₄is added to 1 mL of PMMA C2 and is subjected to vigorous stirring for 48 hrs at room temperature.

Fabrication of thin films and microcavity samples: The DBR substrates were subjected to O₂ plasma treatment for ˜5 mins, which helped having a better spread for the R3B-SMILES solution prior to spin coating. The R3B-SMILES solution was then spin-coated using a two-step recipe at 2000 RPMs (acc=500, t=15 sec) and 4000 RPMs (acc=1000, t=120 sec) onto these O2 plasma-treated DBR substrates. The films are subjected to constant pressure (2500 Pascal) treatment in the dark under room temperature for ˜48 hrs. This is done to maintain a uniform film thickness throughout a large area range (˜2000 microns in XY plane) estimated using the direct method via Profilometer (Bruker Dektak-XT). The thickness value calculated is ˜35 nm. All these films are then carried out for slow evaporation of Ag (0.2 Å/sec) using the e-beam evaporation technique. We deposited 100 nm of top Ag on the top for making the cavity. We use two DBR mirrors with center wavelengths at 2.13 eV and 2.0 eV for the white light reflectivity and PL measurements from the cavity samples, respectively.

Linear Optical Spectroscopy: Angle resolved white light reflectivity measurements were done using emission from broadband tungsten halogen lamp. A telescope (1:1 arrangement) with a 100 μm pinhole at the beam waist was used to collimate the beam. The reflected signal was collected by the 50×, 0.8 numerical aperture (NA) objective (same as the incident beam) followed by deflection from beamsplitter to the spectrometer. Solid-state UV-visible measurements on quartz slides are carried out using a Jasco-760 UV-visible spectrophotometer. Angle resolved PL measurements are performed using a homemade setup comprising laser coupled with a Princeton Instruments monochromator with a PIXIS: 256 electron-multiplying charge-coupled device (emCCD) camera. For both angle resolved white light and PL measurements, the back focal plane of the imaging objective was projected onto the emCCD for single shot dispersion collection. For transient dipole imaging as show in FIG. 2B and 2C; the entire Fourier circle from the imaging lens was projected onto the emCCD in an open slit configuration mapping in-plane momenta kx and ky. A narrow spectral linewidth was chosen for this imaging around the center emission maxima (±10 nm) for better contrast.

Pump Power-dependent Photoluminescence Measurements: The pump beam (530 nm) was generated in a collinear optical parametric amplifier (Light conversion) pumped by the 800 nm output of an amplified Ti: sapphire laser (Coherent Astrella, 10 kHz), and the pump beam was focused onto the sample using the 20× objective (NA=0.40). Our k-space setup (with the kHz repetition rate laser) designed for the power-dependent PL experiments was aligned and calibrated with this microscope objective (20×, 0.40 NA) to monitor the collapse of PL intensity around the lower (ground state) k vectors. Photoluminescence emission was collected in reflection configuration using the spectrometer (Princeton Instruments, Acton SpectraPro SP-2500) and charge-coupled device (CCD) camera (Princeton Instruments, PIX 1024B). The residual excitation beam was blocked using a 550 nm long-pass filter. The real space measurements were carried out with an open slit configuration.

Spatial Interferometry: Spatial coherence measurements were made using a Michelson interferometer configuration. The condensate emission was collected with a20× objective (NA=0.40) objective and directed to a thin non-polarizing beam splitter. One output arm of the beam splitter consisted of a mirror attached to a micrometer screw gauge stage, and the other consisted of a reflector mirror used to invert the image along both the vertical and horizontal axes. After returning through the beam splitter, the two nearly collimated beams were focused onto a CCD (charge-coupled device) using aƒ=12 mm lens, thus providing a ˜47× magnification. A neutral density filter was placed in one arm to equilibrate the intensities and a 550 nm long-pass filter was used to eliminate any residual pump light.

Coupled Oscillator Model: The coupling of the exciton to a single cavity photonic mode is represented by the following Hamiltonian matrix.¹⁵

$$H = ( \begin{matrix}{E}_{ex} - \frac{i ζ ex}{2} & g \\ g & {E}_{cav} - \frac{i ζ cav}{2}\end{matrix} )$$

Wherein g is the coupling strength of the cavity mode with the excitonic resonance and gives the Rabi splitting of interaction as stated in the main text. ζex and ζcaν are the linewidths (fwhm) of the exciton and cavity modes. We solve for the Eigen modes of the above Hamiltonian to get the polariton branch dispersion as a function of in-plane momentum (angles) and fit these with our experimental data for upper, and lower polaritonic branches. Furthermore, we also extract Hopfield coefficients from the same interacting Hamiltonian as shown below.⁶⁰

$$\vert UPB 〉 = C ( k ) \vert exciton 〉 + X ( k ) \vert photon 〉$$

$$\vert LPB 〉 = X ( k ) \vert exciton 〉 - C ( k ) \vert photon 〉$$

where C(k) and X(k) are Hopfiled coefficients³⁷ describing the photon and exciton fraction in the upper (UPB) and lower polariton branches (LPB).

### Patterned Photoluminescent Material

Herein, Focused Ion Beam (FIB) etching is used to pattern a planar microcavity. The 2D exciton-polariton lattice is fabricated by pattering an array of overlapping pillars with different lattice geometries on microcavity using focused ion beam technique. The present approach allowed a study of a variety of polariton condensate lattices at room temperature using a top-down approach without compromising on the quantum yield of the organic excitonic material embedded in the cavity. The realization of exciton-polariton condensate lattices has emerged as an attractive platform for simulating many-body Hamiltonians, and for physical computing architectures.⁶¹⁻⁶⁶

In this research, we present an approach that utilizes Focused Ion Beam (FIB) etching to pattern a planar microcavity. This etching technique enables the realization of high-contrast lattices. We report facile direct realization of two-dimensional exciton-polariton condensate lattice at room temperature by patterning an array of overlapping pillars on planar microcavity using the focused ion beam etching technique.

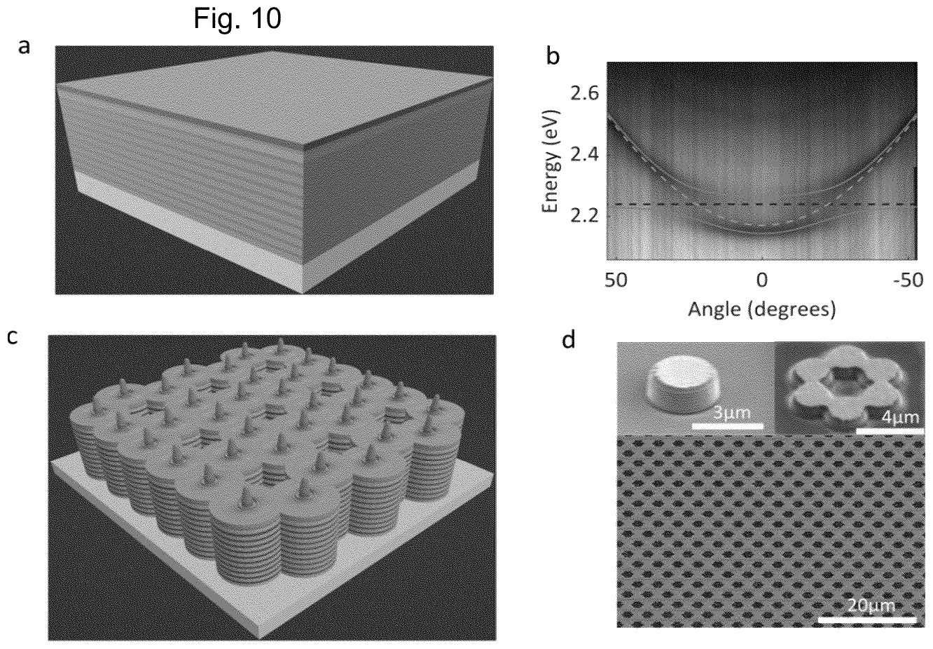

Device fabrication: A strongly coupled organic exciton-polariton microcavity was created on a glass substrate, as shown in FIG. 10a. The cavity was fabricated by depositing a 10.5-pair distributed Bragg reflector (DBR) made of SiO₂/TiO₂ on the glass substrate using pulsed-enhanced chemical vapor deposition (PECVD). The DBR pair's center wavelength and bandwidth were determined to be 620 nm and 200 nm, respectively, using white light angle-dependent reflectivity measurements. After depositing the bottom DBR mirror, a 30 nm thin film of a host-guest based organic material called “small molecules ionic lattice emitters” (SMILES) was spin-coated on the DBR mirror as shown in FIG. 10a. The SMILES complex consists of Rhodamine dye (guest) and cyanostar (host). The choice of SMILES over dye is advantageous due to its high quantum yield and thermal stability in solid-state form. Finally, the microcavity was completed by depositing a 100 nm silver mirror on top of the SMILES using an electron beam evaporator. Using a DBR as the top mirror offers benefits in terms of high-quality factor of the cavity. However, it was avoided in this case to prevent photo bleaching of the organic SMILES film at the high deposition temperatures during pulse enhanced chemical vapor deposition (PECVD).

FIG. 10b displays the reflectivity data, showing two polariton branches: upper and lower polariton, exhibiting an anti-crossing behavior around the energy of the main absorption peak (˜2.190 eV). The anti-crossing was observed at a finite angle due to the negative detuning of the cavity and exciton (˜40 meV). The angle-dependent white light reflectivity data were well-fitted with a coupled oscillator model, yielding an exciton energy of ˜2.190 eV and a cavity mode of ˜2.129 eV. The estimated Rabi splitting from the fit was ˜60 meV, with the cavity being negatively detuned by an energy of ˜40 meV, corresponding to the exciton fraction.

The cavity was patterned using focused ion beam etching (FIB) technique with low ion current (˜77 pA) and 30 kV voltage to avoid heating caused by the gallium ion beam in FIB as shown in FIG. 10c. The microcavity was patterned into different structures such as a single pillar, honeycomb unit cell, and honeycomb lattice, which were characterized using SEM in FIG. 10d.

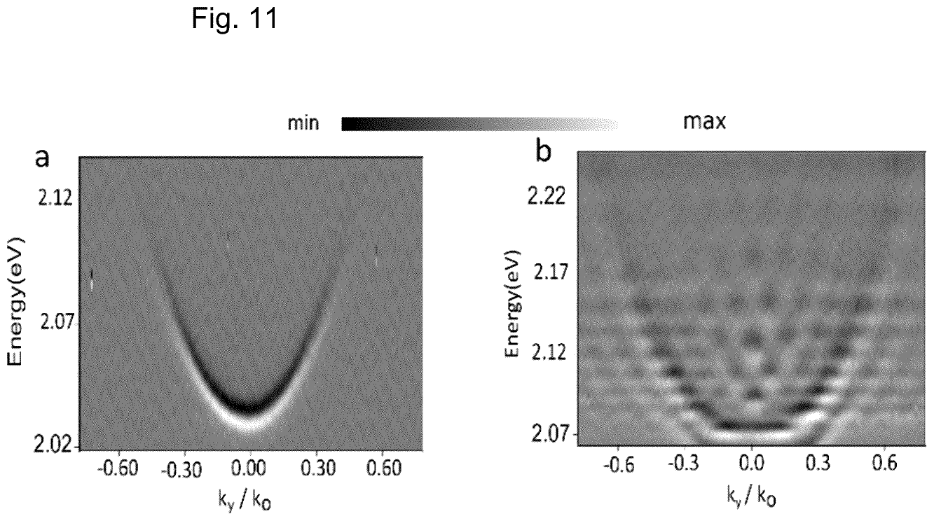

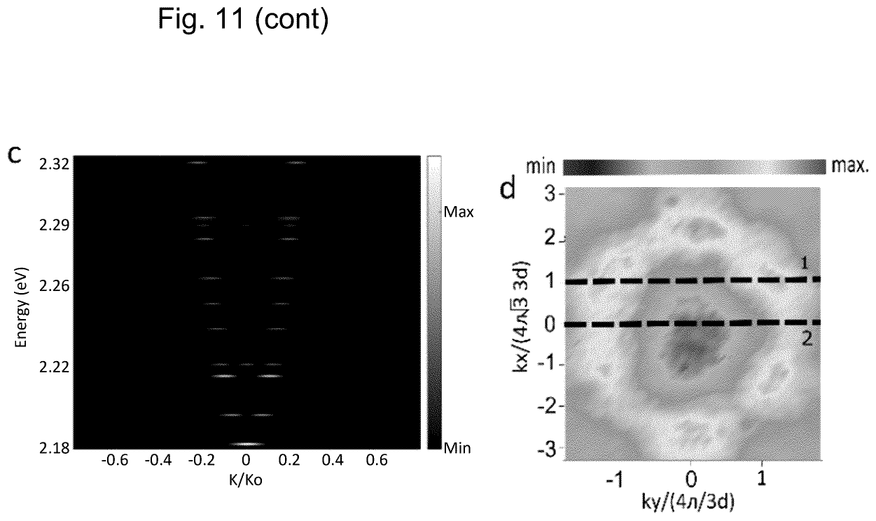

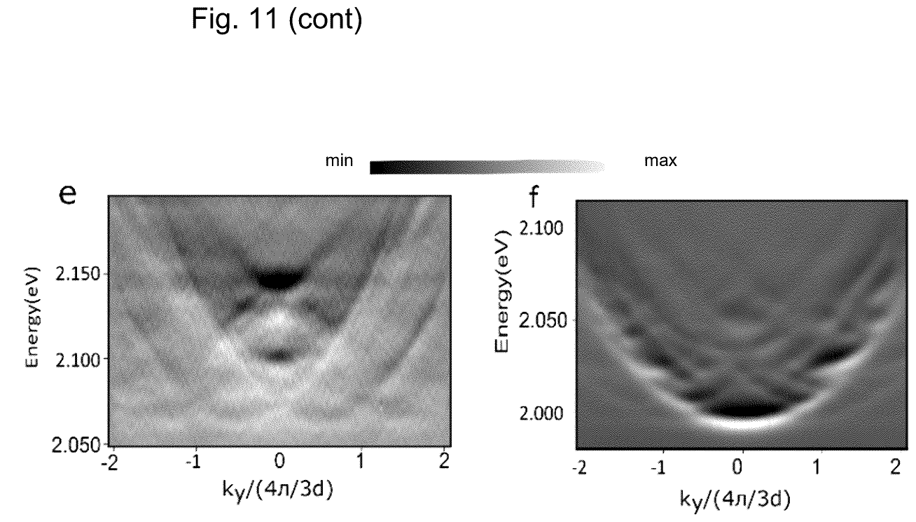

FIG. 11a. presents the photoluminescence (PL) from a 30 nm thin film of SMILES. The strong coupling between SMILES and the cavity was confirmed by measuring the white light angle-dependent reflectivity. FIG. 11a illustrates the angle-dependent photoluminescence (PL) data emitted from the cavity, revealing emission from the lower polariton branch and the absence of emission from the upper polariton branch due to the strongly negatively detuned cavity. The lower polariton branch appears more intense at k=0 compared to finite k due to radiative pumping mechanics in the negatively detuned cavity, where the weakly coupled exciton reservoir pumps the lower polariton branch at k=0.

Comparing FIG. 11a showing emission from non-etched system to the etched system (FIG. 11b) shows generation of localization arising from confined modes of the micropillar. Comparing these to FIG. 11e, which is the emission from the honeycomb lattice, shows production of a band structure.

In the case of the single pillar, the cavity was etched through the active layer, SMILES, and part of the DBR to create a potential trap for polaritons as shown in FIG. 10d. The 3D confinement potential trap experienced by polaritons in single pillar structures, resulting from lateral confinement due to refractive index contrast between the SMILES layer and air, as well as vertical confinement due to the top silver and bottom DBR mirror, modifies the polariton dispersion from a continuous parabolic dispersion to discrete modes. FIG. 11b presents FIM of the photoluminescence from a single pillar, exhibiting discrete states due to the 3D confinement of polaritons. The deep potential trap created by the deep etching technique enhances the visibility of higher-order states, and higher-order modes are clearly visible, with the lowest lying single and double lobe states exhibiting s- and p-type symmetries.

Photoluminescence (PL) from the honeycomb lattice was captured using Fourier space imaging (FIM), employing a non-resonant pulsed laser, 514 nm with a repetition rate of ˜76 MHz and a spot size of 30 μm. In the low excitation limit, the incoherent relaxation of polaritons leads to the population of all energy bands. The first Brillouin zone (BZ) of the lattice was measured using FIM at Dirac energy, as depicted in FIG. 11d. Dirac cones were observed as bright spots at the six corners of the measured first BZ. Energy band structures of the honeycomb polariton lattice were measured along line 1 and line 2 (black lines in FIG. 11d). FIG. 11e displays the energy bands along line 1, exhibiting Dirac points at k/k₀=+1, −1, accompanied by other higher-order energy bands. The measured band structure along line 2, beyond the Dirac point, displays energy bands with a clearly resolved energy gap, as illustrated in FIG. 11f.

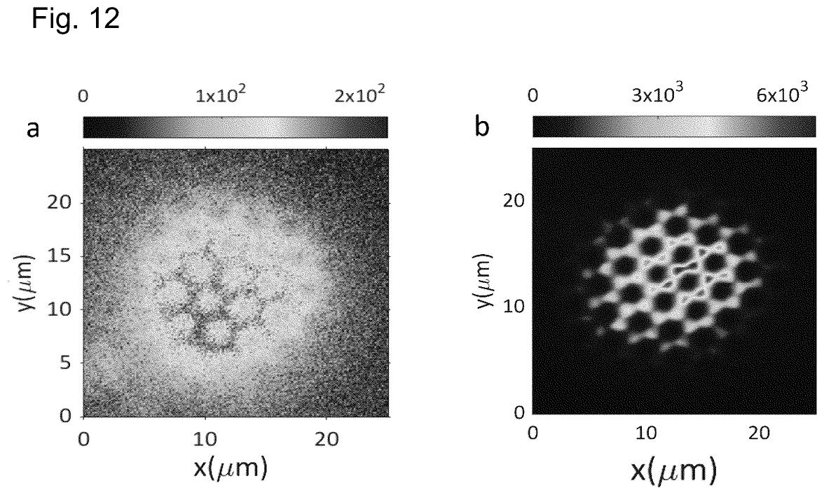

FIG. 12a shows the real space photoluminescence from the HC lattice below threshold, while FIG. 12b shows the PL response above threshold. In that image we observe condensation and coherent light emission (polariton lasing) with a highly localized emission profile.

In the nonlinear regime of interaction in the honeycomb polariton lattice, we investigate the characteristics using input pump power-dependent real-space photoluminescence (PL) and energy-resolved wavevector imaging techniques. The lattice is excited using a flat beam with a spot size of approximately 25 μm, generated by tightly focusing a laser spot on the back focal plane of the objective. FIGS. 12a and 12b illustrate the real-space PL of the lattice before and after reaching the condensation threshold, respectively. A distinct transition is observed from delocalized PL shared by all lattice sites to localized PL specifically at the lattice sites. This transition is evident in FIGS. 12a and 12b.

In conclusion, we have successfully fabricated a room temperature polariton condensate lattice using a top-down fabrication approach with focused ion beam etching on the host-guest based organic material, SMILES microcavity. Experimental and theoretical results demonstrate the confinement of polaritons as discrete states in the energy-resolved angle-dependent photoluminescence (PL) of single micropillars. By patterning a honeycomb lattice on the SMILES microcavity, we have achieved the realization of a polariton lattice. The lattice was characterized by measuring the Brillouin zone at the Dirac energy and the band structure at various planes using Fourier imaging techniques.

Furthermore, we have observed the formation of lattice condensates in the honeycomb polariton lattice through measurements of input power-dependent real space and k-space PL. The results show localized PL at lattice sites and at the Dirac points of the Brillouin zones, respectively. The wavevector-energy-dependent PL reveals the collapse of polaritons in the lower band of the lattice. Additionally, we have demonstrated the nonlinear increase in PL intensity and the decrease in linewidth as a function of input energy density. The disclosed technology enables the study of various polariton condensate lattices at room temperature, while preserving the high quantum yield of the organic excitonic material embedded in the cavity.

Methods: SMILES Microcavity: To prepare the SMILES solution, we followed a previously reported recipe (Benson, C. R., et al. H.Plug-and-Play Optical Materials from Fluorescent Dyes and Macrocycles. Chem 6, 1978-1997 (2020)). The SMILES-based microcavity was fabricated on a quartz substrate with a 500 nm-thick distributed Bragg reflector (DBR) centred at 620 nm. The DBR, composed of 10.5 pairs of SiO₂/TiO₂, was cleaned using O₂ plasma for 5 minutes. A 30 nm-thick SMILES film was then deposited on the cleaned DBR using a spin coating technique with a two-step process. In the first step, the film was spun for 20 seconds at a speed of 1000 rpm, followed by a second step of spinning for 80 seconds at 3000 rpm. The deposited SMILES film was placed in a constant pressure vacuum at 25 degrees Celsius. Finally, a 100 nm-thick silver layer was deposited on top of the SMILES film using an e-beam evaporator, completing the fabrication of the microcavity.

Experimental techniques: We employed near and far field imaging techniques to measure the real space photoluminescence (PL) and Fourier space PL imaging, respectively. For our measurements, we utilized two lasers. To investigate the band structures, we used a 488 nm laser with a repetition rate of 76 MHz to excite the patterned structure on the silver sides of the microcavity. For the excitation of the larger area in the lattice, we created a large laser spot (˜25 μm) by focusing the laser on the back focal plane of the objective lens. The band structure of the lattice was measured using far field imaging techniques, where the back focal plane of the objective lens was imaged in front of a charged coupled device (CCD) camera. Energy-resolved angle-dependent PL was measured by selecting a narrow angle using a narrow slit in front of the CCD camera and dispersing the PL using a 300 grooves per line grating. In addition, we employed a pulsed 532 nm laser with a pulse width of 280 fs and a repetition rate of 1 kHz for our measurements. The real space PL was measured by imaging the near field of the sample using a lens in front of the CCD camera. The Brillouin zone and band structure were measured in a far field imaging configuration in condensed regime.

### REFERENCES

1. Kavokin, A. V.,Baumberg, J. J., Malpuech, G. &Laussy, F. P. Microcavities (Oxford Univ. Press,, 2017).
2. Jiang, Z., Ren, A., Yan, Y., Yao, J. & Zhao, Y. S. Exciton-Polaritons and Their Bose-Einstein Condensates in Organic Semiconductor Microcavities.Adv. Mater.34, 2106095 (2022).
3. Agranovich, V. M., Litinskaia, M. & Lidzey, D. G. Cavity polaritons in microcavities containing disordered organic semiconductors. Phys. Rev. B 67, 085311 (2003).
4. Satapathy, S., Khatoniar, M., Parappuram, D. K., Liu, B., Feist, J., Garcia-Vidal, F. J. & Menon, V. M. Selective isomer emission via funneling of exciton polaritons.Sci. Adv.7, eabj0997 (2021).
5. González-Tudela, A., Huidobro, P.A., Martín-Moreno, L., Tejedor, C. & García-Vidal, F. J. Theory of Strong Coupling between Quantum Emitters and Propagating Surface Plasmons. Phys. Rev. Lett. 110, 126801 (2013).
6. Garcia-Vidal, F. J., Ciuti, C. & Ebbesen, T. W. Manipulating matter by strong coupling to vacuum fields.Angew. Chem. Int. Ed.373, eabd0336 (2021).
7. Ebbesen, T. W. Hybrid Light-Matter States in a Molecular and Material Science Perspective. Acc. Chem. Res.49, 2403-2412 (2016).
8. Liu, B., Rai, P., Grezmak, J., Twieg, R. J. & Singer, K. D. Coupling of exciton-polaritons in low-Qcoupled microcavities beyond the rotating wave approximation. Phys. Rev. B92, 155301 (2015).
9. Kéna-Cohen, S., Maier, S. A. & Bradley, D. D. C. Ultrastrongly Coupled Exciton-Polaritons in Metal-Clad Organic Semiconductor Microcavities. Adv. Opt. Mater.1, 827-833 (2013).
10. Bellessa, J., Bonnand, C., Plenet, J. C. & Mugnier, J. Strong Coupling between Surface Plasmons and Excitons in an Organic Semiconductor. Phys. Rev. Lett. 93, 036404 (2004).
11. Lidzey, D. G. et al. Strong exciton-photon coupling in an organic semiconductor microcavity. Nature395, 53-55 (1998).
12. Garcia-Vidal, F. J., Ciuti, C. & Ebbesen, T. W. Science 2021, 373, eabd0336.
13. Kavokin, A. V.,Baumberg, J. J., Malpuech, G. & Laussy, F. P. Microcavities (Oxford Univ. Press,, 2007).
14. Carusotto, I. & Ciuti, C. Quantum fluids of light. Rev. Mod. Phys. 85, 299-366 (2013).
15. Deng, H., Haug, H. & Yamamoto, Y. Exciton-polariton Bose-Einstein condensation. Rev. Mod. Phys.82, 1489-1537 (2010).
16. Wei, M., Fang, M., Rajendran, S. K., Lai, W. -Y., Turnbull, G. A. & Samuel, I. D. W. Room Temperature Polariton Lasing in Ladder-Type Oligo(p-Phenylene)s with Different x-Conjugation Lengths.Adv. Phot. Res.2, 2000044 (2021).
17. Tang, J., Zhang, J., Lv, Y., Wang, H., Xu, F. F., Zhang, C., Sun, L., Yao, J. & Zhao, Y. S.Room temperature exciton-polariton Bose-Einstein condensation in organic single-crystal microribbon cavities. Nat. Commun. 12, 3265 (2021).
18. Sannikov, D., Yagafarov, T., Georgiou, K.,Zasedatelev, A.,Baranikov, A., Gai, L., Shen, Z., Lidzey, D. & Lagoudakis, P.Room Temperature Broadband Polariton Lasing from a Dye-Filled Microcavity. Adv. Opt. Mater.7, 1900163 (2019).
19. Zasedatelev, A. V.,Baranikov, A. V., Urbonas, D.,Scafirimuto, F., Scherf, U.,Stöferle, T., Mahrt, R. F. & Lagoudakis, P. G. A room-temperature organic polariton transistor. Nat. Photonics13, 378-383 (2019).
20 Lerario, G.,Fieramosca, A., Barachati, F., Ballarini, D., Daskalakis, K. S., Dominici, L., De Giorgi, M., Maier, S. A., Gigli, G., Kéna-Cohen, S. & Sanvitto, D. Room-temperature superfluidity in a polariton condensate. Nat. Phys. 13, 837-841 (2017).
21. Ballarini, D., Gianfrate, A., Panico, R., Opala, A., Ghosh, S., Dominici, L., Ardizzone, V., De Giorgi, M., Lerario, G., Gigli, G., Liew, T. C. H., Matuszewski, M. & Sanvitto, D. Polaritonic Neuromorphic Computing Outperforms Linear Classifiers. ACS Nano Lett. 20, 3506-3512 (2020).
22. Jayaprakash, R., Whittaker, C. E., Georgiou, K., Game, O. S., McGhee, K. E., Coles, D. M. & Lidzey, D. G. Two-Dimensional Organic-Exciton Polariton Lattice Fabricated Using Laser Patterning. ACS Photonics7, 2273-2281 (2020).
23. Scafirimuto, F., Urbonas, D., Becker, M. A., Scherf, U., Mahrt, R. F. & Stoferle, T. Tunable exciton-polariton condensation in a two-dimensional Lieb lattice at room temperature. Commun. Phys. 4, 39 (2021).
24. Scafirimuto, F., Urbonas, D., Scherf, U., Mahrt, R. F. & Stöferle, T. Room-Temperature Exciton-Polariton Condensation in a Tunable Zero-Dimensional Microcavity. ACS Photonics5, 85-89 (2018).
25. Urbonas, D., Stoferle, T., Scafirimuto, F., Scherf, U. & Mahrt, R.F. Zero-Dimensional Organic Exciton-Polaritons in Tunable Coupled Gaussian Defect Microcavities at Room Temperature. ACS Photonics3, 1542-1545 (2016).
26. Dusel, M., Betzold, S., Harder, T. H., Emmerling, M., Beierlein, J., Ohmer, J., Fischer, U., Thomale, R., Schneider, C., Höfling, S. & Klembt, S. Room-Temperature Topological Polariton Laser in an Organic Lattice. ACS Nano Letters21, 6398-6405 (2021).
27. Dusel, M., Betzold, S., Egorov, O. A., Klembt, S., Ohmer, J., Fischer, U., Höfling, S. & Schneider, C. Room temperature organic exciton-polariton condensate in a lattice. Nat. Commun.11, 2863 (2020).
28. Keeling, J. & Kéna-Cohen, S. Bose-Einstein Condensation of Exciton-Polaritons in Organic Microcavities. Ann. Rev. Phys. Chem.71, 435-459 (2020).
29. Ren, J., Liao, Q., Huang, H., Li, Y., Gao, T., Ma, X., Schumacher, S., Yao, J., Bai, S. & Fu, H. Efficient Bosonic Condensation of Exciton Polaritons in an H-Aggregate Organic Single-Crystal Microcavity. ACS Nano Lett.20, 7550-7557 (2020).
30. Kéna-Cohen, S. & Forrest, S. R. Room-temperature polariton lasing in an organic single-crystal microcavity. Nat. Photon.4, 371-375 (2010).
31. Wei, M., Rajendran, S. K., Ohadi, H., Tropf, L., Gather, M. C., Turnbull, G. A. &Samuel, I. D. W. Low-threshold polariton lasing in a highly disordered conjugated polymer. Optica6, 1124-1129 (2019).
32 Plumhof, J. D., Stoferle, T., Mai, L., Scherf, U. & Mahrt, R. F. Room-temperature Bose-Einstein condensation of cavity exciton-polaritons in a polymer. Nat. Mater. 13, 247-252 (2014).
33. Daskalakis, K. S., Maier, S. A., Murray, R. & Kéna-Cohen, S. Nonlinear interactions in an organic polariton condensate. Nat. Mater.13, 271-278 (2014).
34. Cookson, T., Georgiou, K., Zasedatelev, A., Grant, R. T., Virgili, T., Cavazzini, M., Galeotti, F., Clark, C., Berloff, N. G., Lidzey, D. G.& Lagoudakis, P. G. A Yellow Polariton Condensate in a Dye Filled Microcavity. Adv. Opt. Mater.5, 1700203 (2017).
35. Dietrich, C. P., Steude, A., Tropf, L., Schubert, M., Kronenberg, N. M., Ostermann, K., Höfling, S.& Gather, M. C. An exciton-polariton laser based on biologically produced fluorescent protein. Sci. Adv.2, e1600666 (2016).
36. Betzold, S., Dusel, M., Kyriienko, O., Dietrich, C. P., Klembt, S., Ohmer, J., Fischer, U.; Shelykh, I. A., Schneider, C.& Höfling, S. Coherence and Interaction in Confined Room-Temperature Polariton Condensates with Frenkel Excitons. ACS Photonics7, 384-392 (2020).
37. Chang, M. H., Frampton, M. J., Anderson, H. L. & Herz, L. M. Intermolecular Interaction Effects on the Ultrafast Depolarization of the Optical Emission from Conjugated Polymers. Phys. Rev. Lett.98, 027402 (2007).
38. Musser, A. J., Rajendran, S. K., Georgiou, K., Gai, L., Grant, R. T., Shen, Z., Cavazzini, M., Ruseckas, A., Turnbull, G. A., Samuel, I. D. W., Clark, J.& Lidzey, D. G. Intermolecular states in organic dye dispersions: excimers vs. aggregates. J. Mater. Chem. C 5, 8380-8389 (2017).
39. Benson, C. R., Kacenauskaite, L., VanDenburgh, K. L., Zhao, W., Qiao, B., Sadhukhan, T., Pink, M., Chen, J., Borgi, S., Chen, C. -H., Davis, B. J., Simon, Y. C., Raghavachari, K., Laursen, B. W. & Flood, A. H.Plug-and-Play Optical Materials from Fluorescent Dyes and Macrocycles. Chem 6, 1978-1997 (2020).
40. Satapathy, S., Liu, B., Deshmukh, P., Molinaro, P. M., Dirnberger, F., Khatoniar, M., Koder, R. L. & Menon, V. M. Thermalization of Fluorescent Protein Exciton-Polaritons at Room Temperature. Adv. Mater.34, 2109107 (2022).
41. Dietrich, C. P., Steude, A., Schubert, M., Ohmer, J., Fischer, U., Höfling, S.& Gather, M. C. Strong Coupling in Fully Tunable Microcavities Filled with Biologically Produced Fluorescent Proteins. Adv. Opt. Mater.5, 1600659 (2017).
42. Dietrich, C. P., Karl, M., Ohmer, J., Fischer, U., Gather, M. C. & Hofling, S. Molding Photonic Boxes into Fluorescent Emitters by Direct Laser Writing. Adv. Mater.29, 1605236 (2017).
43. Kim, J., Zhao, H., Hou, S., Khatoniar, M., Menon, V. & Forrest, S. R. Using Fourier-Plane Imaging Microscopy for Determining Transition-Dipole-Moment Orientations in Organic Light-Emitting Devices. Phys. Rev. App. 14, 034048 (2020).
44. Coles, D. M., Michetti, P., Clark, C., Tsoi, W. C., Adawi, A. M., Kim, J. -S. & Lidzey, D. G. Vibrationally assisted polariton-relaxation processes in strongly coupled organic-semiconductor microcavities. Adv. Funct. Mater.21, 3691-3696 (2011).
45. Somaschi, N., Mouchliadis, L., Coles, D., Perakis, I. E., Lidzey, D. G., Lagoudakis, P. G. & Savvidis, P. G. Ultrafast polariton population build-up mediated by molecular phonons in organic microcavities. Appl. Phys. Lett 99, 209 (2011).
46. Michetti, P. & La Rocca, G. Exciton-phonon scattering and photoexcitation dynamics in J-aggregate microcavities. Phys. Rev. B79, 035325 (2009).
47. Mazza, L., Kéna-Cohen, S., Michetti, P. & La Rocca, G. C. Microscopic theory of polariton lasing via vibronically assisted scattering. Phys. Rev. B88, 075321 (2013).
48. Deng, H., Press, D., Götzinger, S., Solomon, G. S., Hey, R., Ploog, K. H.& Yamamoto, Y. Quantum degenerate exciton-polaritons in thermal equilibrium. Phys. Rev. Lett.97, 146402 (2006).
49. Maragkou, M., Grundy, A. J. D., Ostatnický, T. & Lagoudakis, P. G. Longitudinal optical phonon assisted polariton laser. Appl. Phys. Lett.97, 111110 (2010).
50. Kasprzak, J., Richard, M., Kundermann, S., Baas, A.,Jeambrun, P., Keeling, J. M. J., Marchetti, F. M., Szymańska, M. H., André, R.,Staehli, J. L., Savona, V., Littlewood, P. B.,Deveaud, B.& Dang, L. S. Bose-Einstein condensation of exciton polaritons. Nature443, 409-414 (2006).
51. Porras, D & Tejedor, C. Linewidth of a polariton laser: Theoretical analysis ofself-interaction effects. Phys. Rev. B67, 161310 (2003).
52. Ohadi, H., Kammann, E., Liew, T. C. H., Lagoudakis, K. G., Kavokin, A. V. & Lagoudakis, P. G. Spontaneous symmetry breaking in a polariton and photon laser. Phys. Rev. Lett. 109, 016404 (2012).
53. Deng, H., Solomon, G. S., Hey, R., Ploog, K. H. & Yamamoto, Y. Spatial Coherence of a Polariton Condensate. Phys. Rev. Lett.99, 126403 (2007).
54. Daskalakis, K. S., Maier, S. A. & Kéna-Cohen, S. Spatial Coherence and Stability in a Disordered Organic Polariton Condensate. Phys. Rev. Lett. 115, 035301 (2015).
55. Putintsev, A., Zasedatelev, A., McGhee, K. E., Cookson, T., Georgiou, K., Sannikov, D., Lidzey, D. G. & Lagoudakis, P. G. Nano-second exciton-polariton lasing in organic microcavities. Appl. Phys. Lett.117, 123302 (2020).
56. McGhee, K. E., Putintsev, A., Jayaprakash, R., Georgiou, K., O′Kane, M. E., Kilbride, R. C., Cassella, E. J.,Cavazzini, M., Sannikov, D. A., Lagoudakis, P. G. & Lidzey, D. G. Polariton condensation in an organic microcavity utilising a hybrid metal-DBR mirror. Sci. Rep. 11, 20879 (2021).
57. Ishii, T., Miyata, K.,Mamada, M., Bencheikh, F.,Mathevet, F., Onda, K., Kéna-Cohen, S. & Adachi, C. Low-Threshold Exciton-Polariton Condensation via Fast Polariton Relaxation in Organic Microcavities. Adv. Opt. Mater.9, 2102034 (2021).
58. Rajendran, S. K., Wei, M., Ohadi, H., Ruseckas, A., Turnbull, G. A. & Samuel, I. D. W. Low Threshold Polariton Lasing from a Solution-Processed Organic Semiconductor in a Planar Microcavity. Adv. Opt. Mater.7, 1801791 (2019).
59. Lee, S., Chen, C. -H. & Flood, A. H. A pentagonal cyanostar macrocycle with cyanostilbene CH donors binds anions and forms dialkylphosphate [3] rotaxanes. Nat. Chem.5, 704-710 (2013).
60. Hopfield, J. J. Phys. Rev. 112, 1555 (1958).
61. Lagoudakis, Pavlos G., and Natalia G. Berloff. “A polariton graph simulator.” New Journal of Physics 19, no. 12 (2017): 125008.
62. Berloff, Natalia G., Matteo Silva, Kirill Kalinin, Alexis Askitopoulos, Julian D. Töpfer, Pasquale Cilibrizzi, Wolfgang Langbein, and Pavlos G. Lagoudakis. “Realizing the classical XY Hamiltonian in polariton simulators.” Nature materials 16, no. 11 (2017): 1120-1126.
63. Amo, Alberto, and Jacqueline Bloch. “Exciton-polaritons in lattices: A non-linear photonic simulator.” Comptes Rendus Physique 17, no. 8 (2016): 934-945.
64 Kavokin, Alexey, Timothy CH Liew, Christian Schneider, Pavlos G. Lagoudakis, Sebastian Klembt, and Sven Hoefling. “Polariton condensates for classical and quantum computing.” Nature Reviews Physics 4, no.7 (2022): 435-451.
65. Ballarini, Dario, Antonio Gianfrate, Riccardo Panico, Andrzej Opala, Sanjib Ghosh, Lorenzo Dominici, Vincenzo Ardizzone et al. “Polaritonic neuromorphic computing outperforms linear classifiers.” Nano Letters 20, no. 5 (2020): 3506-3512.
66 Ghosh, Sanjib, and Timothy CH Liew. “Quantum computing with exciton-polariton condensates.” npj Quantum Information 6, no. 1 (2020): 16.

1. A microcavity comprising a photoluminescent material positioned between two reflectors, wherein the photoluminescent material comprises a cationic molecular dye, a macrocyclic anion receptor host, and an anion embedded within the macrocyclic anion receptor host.

2. The microcavity of claim 1, wherein the macrocyclic anion receptor host comprises a polycyanostilbene.

3. The microcavity of claim 2, wherein the macrocyclic anion receptor host is a polycyanostilbene of formula: 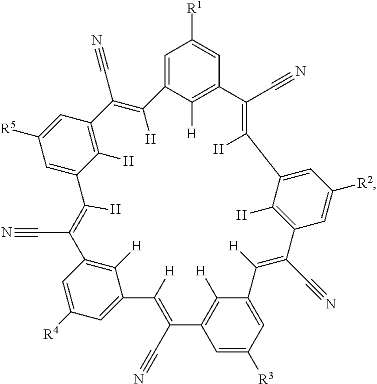
wherein R1, R2, R3, R4 and R5 are each independently selected from the group consisting of alkenyl, alkyl, alkoxy, alkyl-NH-alkyl, aryl, cycloalkyl, heteroaryl, heterocycle, haloalkyl, hydrogen, iodo, —OR6, —N(R7R8), —CO2R9, —C(O)—N(R10Rn), and
wherein R6, R7, R8, R9, R10, and R11 are each independently selected from the group consisting of alkenyl, alkyl, alkoxy, alkyl-NH-alkyl, aryl, arylalkyl, cycloalkyl, heteroaryl, heterocycle, haloalkyl, and hydrogen.

4. The microcavity of claim 3, wherein the macrocyclic anion receptor host is

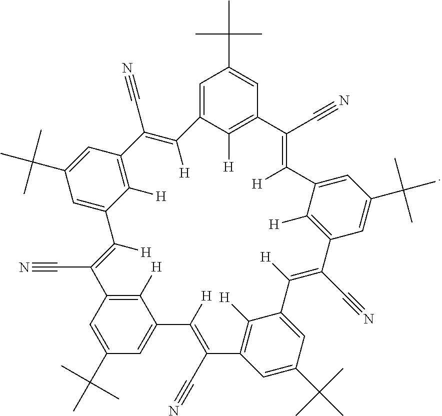 [SMILES: CC(C)(C)c1cc2cc(c1)/C(C#N)=C/c1cc(cc(C(C)(C)C)c1)/C(C#N)=C/c1cc(cc(C(C)(C)C)c1)/C(C#N)=C/c1cc(cc(C(C)(C)C)c1)/C(C#N)=C/c1cc(cc(C(C)(C)C)c1)/C(C#N)=C/2]

5. The microcavity of claim 1, wherein the positioning of the reflectors is chosen to allow a standing wave through the photoluminescent material.

6. The microcavity of claim 5, wherein at least one of the reflectors is a distributed Bragg reflector or a mirror.

7. The microcavity of claim 5, wherein one of the reflectors is the distributed Bragg reflector and another one of the reflectors is the mirror.

8. The microcavity of claim 5, wherein a cavity detuning is chosen to keep the energy difference between the uncoupled exciton and k0 of an LP mode to be in resonance with a vibron of the photoluminescent material.

9. The microcavity of claim 1, wherein the photoluminescent material is a thin film.

10. The microcavity of claim 1, wherein the photoluminescent material is patterned.

11. The microcavity of claim 1, wherein the molecular dye is selected from a group consisting of a cationic rhodamine dye, cationic styryl dye, cationic xanthene, cationic triangulenium dye, cationic oxazine dye, cationic triarylmethane dye, cationic cyanine dye, cationic acridine dye, cationic fluoronone dye, cationic phenanthridine dye, cationic polyaromatic hydrocarbon dye, cationic imide dye, cationic BODIPY dye, cationic coumarin dye, cationic squaraine dye, and any combination thereof.

12. The microcavity of claim 11, wherein the molecular dye is a cationic rhodamine dye.

13. The microcavity of claim 1, wherein the stoichiometric ratio of cationic molecular dye or the anion to the macrocyclic anion receptor host is between 2.0:1.0 and 1.0:4.0.

14. The microcavity of claim 1, wherein the cationic molecular dye and the macrocyclic anion receptor host are arranged in a repeating constitutional unit and the macrocyclic anion receptor host isolates the cationic molecular dye.

15. A method for forming a polariton comprising irradiating the microcavity of claim 1.

16. The method of claim 15, wherein the polariton is formed at room temperature.

17. A method comprising emitting a photon from an irradiated microcavity of claim 1.

18. A method for preparing a microcavity, the method comprising forming the photoluminescent material according to claim 1 onto a reflector substrate.

19. The method of claim 18 further comprising, forming a reflector on the formed photoluminescent material opposite to the reflector substrate.

20. The method claim 18, further comprising patterning of the formed photoluminescent material.

21. The method of claim 18, wherein forming the photoluminescent material comprises depositing a solution, the solution comprising the cationic molecular dye, the macrocyclic anion receptor host, and the anion, and evaporating solvent from the deposited solution.

22. The method of claim 18, wherein the formed photoluminescent material is prepared by spin coating the reflector substrate with a solution, the solution comprising the cationic molecular dye, the macrocyclic anion receptor host, and the anion, and evaporating the solvent.
